(19) United States
(12) Patent Application Publication
(10) Pub. No.: US 2026/0245504 A1
(43) Pub. Date: Aug. 20, 2026

(54) ARRAY SUBSTRATE AND DISPLAY PANEL

(71) Applicant: Kunshan Govisionox Optoelectronics Co., Ltd., Kunshan (CN)

(72) Inventors: Fa-Hsyang CHEN, Kunshan (CN); Mengsen WANG, Kunshan (CN); Zidong GUO, Kunshan (CN); Enqing GUO, Kunshan (CN); Cuili GAI, Kunshan (CN); Wangfeng XI, Kunshan (CN); Xiujian ZHU, Kunshan (CN)

(73) Assignee: Kunshan Govisionox Optoelectronics Co., Ltd., Kunshan (CN)

(21) Appl. No.: 19/642,597

(22) Filed: Apr. 8, 2026

(30) Foreign Application Priority Data
Apr. 14, 2025 (CN) 202510465474.1

(51) Int. Cl. G09G 3/32; G09G 3/20; H10D 86/40

(52) U.S. Cl. CPC G09G 3/32; G09G 3/2007; H10D 86/441; H10D 86/451; G09G 2300/0819; G09G 2300/0852; G09G 2300/0861; G09G 2320/0233

(57) ABSTRACT

The present application discloses an array substrate and a display panel. The array substrate includes a pixel circuit, the pixel circuit includes a first switching transistor and a driving transistor; the first switching transistor is connected to the driving transistor, the first switching transistor is configured to control a gate potential and a first electrode potential of the driving transistor, and the driving transistor is configured to form a driving current according to the gate potential and the first electrode potential; a threshold voltage of the driving transistor is greater than a threshold voltage of the first switching transistor.

### CROSS-REFERENCE TO RELATED APPLICATIONS

The present application claims priority to the Chinese Patent Application 202510465474.1, filed on April 14, 2025, and the entire contents of the aforementioned application are hereby incorporated by reference in its entirety.

### FIELD

The present application belongs to the field of display technology, and particularly relates to an array substrate and a display panel.

### BACKGROUND

A display panel may use all-oxide thin film transistors to form circuits to drive light-emitting devices to emit light, giving the display panel characteristics of low cost and excellent large-area uniformity. Because the electrical parameter range of all-oxide thin film transistors that matches circuits is relatively narrow, during the formation of the display panel, it is easy for the electrical parameter range of the all-oxide thin film transistors to fail to match the circuits, resulting in poor display performance of the display panel.

### SUMMARY

The present disclosure provides an array substrate and a display panel to improve the matching between the electrical parameter range of transistors and circuits, thereby enhancing the display performance of the display panel.

In a first aspect, an embodiment of the present disclosure provides an array substrate, including a pixel circuit, the pixel circuit including a first switching transistor and a driving transistor; the first switching transistor is connected to the driving transistor, the first switching transistor is configured to control a gate potential and a first electrode potential of the driving transistor, and the driving transistor is configured to form a driving current according to the gate potential and the first electrode potential; a threshold voltage of the driving transistor is greater than a threshold voltage of the first switching transistor.

In a second aspect, an embodiment of the present disclosure further provides an array substrate, including a gate driving circuit; the gate driving circuit includes a second switching transistor and an output transistor, the second switching transistor is connected to the output transistor, and the output transistor is configured to output a gate driving signal; the output transistor includes a third top gate and a third bottom gate; the third top gate is connected to the second switching transistor, and the third bottom gate is configured to receive a first voltage; and the first voltage is adjustable.

In a third aspect, an embodiment of the present disclosure further provides a display panel, including the array substrate according to the embodiments and the second aspect.

According to the embodiments of the present disclosure, by setting the threshold voltage of the driving transistor to be greater than that of the first switching transistor, the driving capability of the driving transistor can be made greater than that of the first switching transistor, ensuring that the driving transistor can achieve grayscale expansion, and improving the matching between the electrical parameter range of the driving transistor and the pixel circuit. At the same time, the switching speed of the first switching transistor is ensured, guaranteeing the matching between the electrical parameter range of the first switching transistor and the pixel circuit, enabling the pixel circuit to simultaneously consider both the switching speed of the first switching transistor and the driving capability of the driving transistor, thereby improving the display performance of the display panel.

### BRIEF DESCRIPTION OF THE DRAWINGS

FIG. 1 is a schematic top view structural diagram of an array substrate provided by an embodiment of the present disclosure;

FIG. 2 is a schematic structural diagram of a pixel circuit provided by an embodiment of the present disclosure;

FIG. 3 is a schematic cross-sectional structural diagram of an array substrate provided by an embodiment of the present disclosure;

FIG. 4 is a schematic cross-sectional structural diagram of another array substrate provided by an embodiment of the present disclosure;

FIG. 5 is a schematic cross-sectional structural diagram of another array substrate provided by an embodiment of the present disclosure;

FIG. 6 is a schematic cross-sectional structural diagram of another array substrate provided by an embodiment of the present disclosure;

FIG. 7 is a schematic cross-sectional structural diagram of another array substrate provided by an embodiment of the present disclosure;

FIG. 8 is a schematic top view structural diagram of another array substrate provided by an embodiment of the present disclosure;

FIG. 9 is a schematic structural diagram of a gate driving circuit provided by an embodiment of the present disclosure;

FIG. 10 is a schematic cross-sectional structural diagram of another array substrate provided by an embodiment of the present disclosure;

FIG. 11 is a schematic diagram illustrating the correlation between the threshold voltage of an output transistor and the performance of a gate driving circuit provided by an embodiment of the present disclosure;

FIG. 12 is a schematic diagram illustrating the correlation between the threshold voltage of a second switching transistor and the performance of a gate driving circuit provided by an embodiment of the present disclosure;

FIG. 13 is a schematic structural diagram of a display panel provided by an embodiment of the present disclosure.

### DETAILED DESCRIPTION OF THE EMBODIMENTS

The following describes the present disclosure in further detail with reference to the accompanying drawings and embodiments. It should be understood that the specific embodiments described herein are merely for explaining the present disclosure and are not intended to limit the present disclosure. It should also be noted that, for ease of description, only parts related to the present disclosure, rather than the entire structure, are shown in the accompanying drawings.

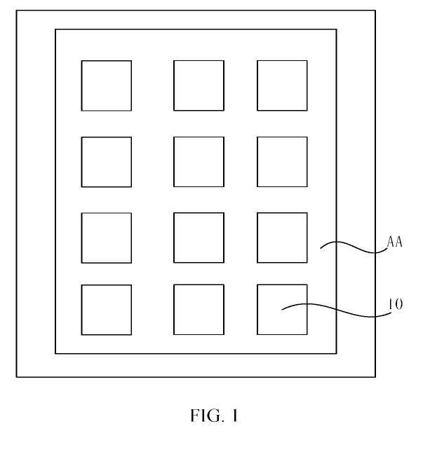

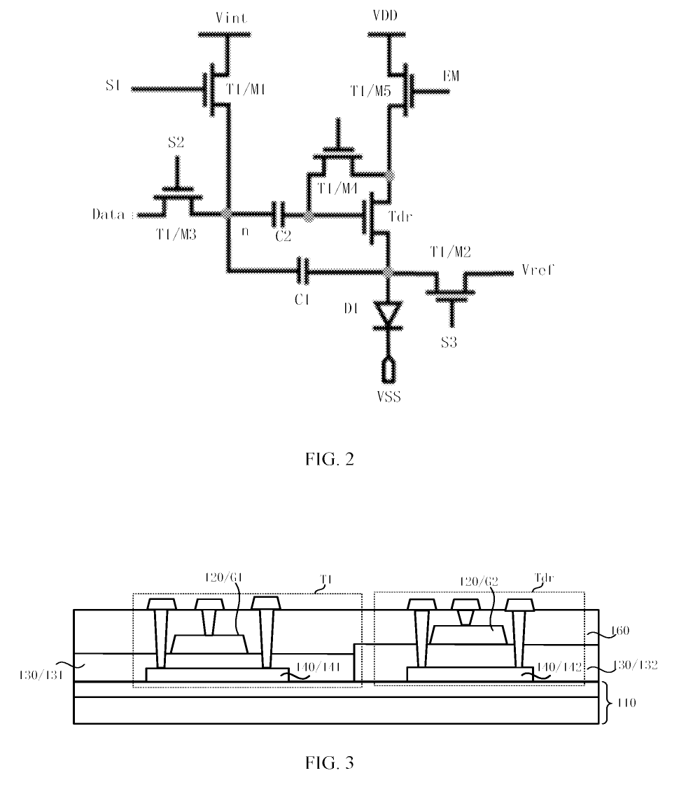

FIG. 1 is a schematic top view of an array substrate provided by an embodiment of the present disclosure, and FIG. 2 is a schematic structural diagram of a pixel circuit provided by an embodiment of the present disclosure. As shown in FIG. 1 and FIG. 2, the array substrate includes a pixel circuit 10, and the pixel circuit 10 includes a first switching transistor T1 and a driving transistor Tdr. The first switching transistor T1 is connected to the driving transistor Tdr, the first switching transistor T1 is configured to control a gate potential and a first electrode potential of the driving transistor Tdr, and the driving transistor Tdr is configured to form a driving current according to the gate potential and the first electrode potential. A threshold voltage of the driving transistor Tdr is greater than a threshold voltage of the first switching transistor T1.

In some embodiments, as shown in FIG. 1, the array substrate may include a display area AA, and the pixel circuit 10 is disposed in the display area AA. When the display area AA includes a plurality of pixel circuits 10, the plurality of pixel circuits 10 may be regularly arranged in the display area AA, for example, arranged in an array. The pixel circuit 10 includes the first switching transistor T1 and the driving transistor Tdr. The first switching transistor T1 is connected to the driving transistor Tdr, and can control the gate potential and the first electrode potential of the driving transistor Tdr according to an input driving signal, and the driving transistor Tdr can form a driving current according to the input driving signal. After the array substrate forms a display panel, a light-emitting device is further disposed in the display area AA. The driving transistor Tdr is connected to the light-emitting device and is configured to provide a driving current to the light-emitting device to drive the light-emitting device to emit light, thereby enabling display of the display panel.

In some embodiments, FIG. 2 exemplarily shows that the pixel circuit 10 includes five first switching transistors T1, the driving transistor Tdr, and two capacitors. The five first switching transistors T1, the driving transistor Tdr, and the two capacitors constitute a 6T2C pixel circuit. The five first switching transistors T1 may be respectively a first initialization transistor M1, a second initialization transistor M2, a data writing transistor M3, a threshold compensation transistor M4, and an emission control transistor M5. The two capacitors are respectively a first capacitor C1 and a second capacitor C2. During operation of the pixel circuit 10, in a first phase, a first scan signal S1 may control the first initialization transistor M1 and the threshold compensation transistor M4 to be turned on. A first initialization signal Vint is transmitted to a first node n through the first initialization transistor M1, and a gate of the driving transistor Tdr is initialized through the second capacitor C2, causing the driving transistor Tdr to be turned on. Then, threshold compensation is performed on the driving transistor Tdr through the threshold compensation transistor M4. In a second phase, a second scan signal S2 controls the data writing transistor M3 to be turned on. A data signal Data is written into the first capacitor C1 and the second capacitor C2 through the data writing transistor M3, and is coupled to the gate of the driving transistor Tdr according to the first capacitor C1 and the second capacitor C2, and the gate potential of the driving transistor Tdr is the data signal after threshold compensation. In a third phase, an emission control signal EM controls the emission control transistor M5 to be turned on. A first power supply VDD is transmitted to the first electrode of the driving transistor Tdr through the emission control transistor M5. The driving transistor Tdr forms a driving current according to the gate potential and the first electrode potential to drive the light-emitting device D1 to emit light. In a fourth phase, a third scan signal S3 controls the second initialization transistor M2 to be turned on. A second initialization signal Vref initializes an anode of the light-emitting device D1 through the second initialization transistor M2. A cathode of the light-emitting device D1 is input with a second power supply VSS, and the second power supply VSS is less than the first power supply VDD. As can be seen from the above process, by controlling different first switching transistors T1 to be turned on or off through scan signals and the emission control signal, the gate potential and the first electrode potential of the driving transistor Tdr can be controlled, and the driving transistor Tdr can form a driving current according to the data signal to drive the light-emitting device D1 to emit light.

During operation of the pixel circuit 10, the first switching transistor T1, as a switching transistor, can control whether a signal is transmitted. The driving transistor Tdr, as a driving transistor, can form a driving current according to the data signal. By setting the threshold voltage of the driving transistor Tdr to be greater than the threshold voltage of the first switching transistor T1, the driving capability of the driving transistor Tdr can be made greater than the driving capability of the first switching transistor T1, ensuring that the driving transistor Tdr can achieve grayscale expansion and improving the adaptability between the electrical characteristic range of the driving transistor Tdr and the pixel circuit 10. At the same time, the switching speed of the first switching transistor T1 is ensured, and the adaptability between the electrical characteristic range of the first switching transistor T1 and the pixel circuit 10 is ensured, enabling the pixel circuit 10 to simultaneously take into account the switching speed of the first switching transistor T1 and the driving capability of the driving transistor Tdr, thereby improving the display effect of the display panel.

In this embodiment, by setting the threshold voltage of the driving transistor to be greater than the threshold voltage of the first switching transistor, the driving capability of the driving transistor can be made greater than the driving capability of the first switching transistor, ensuring that the driving transistor can achieve grayscale expansion and improving the adaptability between the electrical characteristic range of the driving transistor and the pixel circuit. At the same time, the switching speed of the first switching transistor is ensured, and the adaptability between the electrical characteristic range of the first switching transistor and the pixel circuit is ensured, enabling the pixel circuit to simultaneously take into account the switching speed of the first switching transistor and the driving capability of the driving transistor, thereby improving the display effect of the display panel.

FIG. 3 is a schematic cross-sectional structural diagram of an array substrate provided by an embodiment of the present disclosure. As shown in FIG. 3, the array substrate further includes: a substrate 110; a gate layer 120 disposed on one side of the substrate 110, the gate layer 120 including a first gate G1 of a first switching transistor T1 and a second gate G2 of a driving transistor Tdr; a gate insulating layer 130 disposed on one side of the gate layer 120, the gate insulating layer 130 including a first gate insulating layer 131 and a second gate insulating layer 132, an orthographic projection of the first gate G1 on the substrate 110 being located within an orthographic projection of the first gate insulating layer 131 on the substrate 110, an orthographic projection of the second gate G2 on the substrate 110 being located within an orthographic projection of the second gate insulating layer 132 on the substrate 110; a thickness of the second gate insulating layer 132 being greater than a thickness of the first gate insulating layer 131; a semiconductor layer 140 disposed on a side of the gate insulating layer 130 away from the gate layer 120, the semiconductor layer 140 including a first active region 141 and a second active region 142, an orthographic projection of the first active region 141 on the substrate 110 overlapping with the orthographic projection of the first gate G1 on the substrate 110, an orthographic projection of the second active region 142 on the substrate 110 overlapping with the orthographic projection of the second gate G2 on the substrate 110.

In some embodiments, the first switching transistor T1 and the driving transistor Tdr can be formed simultaneously through the same process, where identical film layer structures of the first switching transistor T1 and the driving transistor Tdr are formed by sharing the same film layer. During the manufacturing process of the array substrate, the gate layer 120 can be formed on the substrate 110 first, and then the gate layer 120 is patterned to simultaneously form the first gate G1 of the first switching transistor T1 and the second gate G2 of the driving transistor Tdr. When the gate insulating layer 130 is disposed on a side of the gate layer 120 away from the substrate 110, after forming the first gate G1 of the first switching transistor T1 and the second gate G2 of the driving transistor Tdr, the gate insulating layer 130 can be formed on the side of the gate layer 120 away from the substrate 110, the portion opposite to the first gate G1 is the first gate insulating layer 131 of the first switching transistor T1, the portion opposite to the second gate G2 is the second gate insulating layer 132 of the driving transistor Tdr, then the semiconductor layer 140 is formed and patterned to form the first active region 141 and the second active region 142. In this case, the first switching transistor T1 and the driving transistor Tdr are bottom-gate transistors. When the gate insulating layer 130 is disposed on a side of the gate layer 120 close to the substrate 110, the semiconductor layer 140 can be formed first for forming the first active region 141 and the second active region 142, then the gate insulating layer 130 is formed on a side of the semiconductor layer 140 away from the substrate 110, and then the gate layer 120 is formed and patterned to form the first gate G1 and the second gate G2. In this case, the first switching transistor T1 and the driving transistor Tdr are top-gate transistors. The first active region 141 is the active layer of the first switching transistor T1, used for forming the source/drain region and the channel region of the first switching transistor T1. The second active region 142 is the active layer of the driving transistor Tdr, used for forming the source/drain region and the channel region of the driving transistor Tdr.

The thickness of the second gate insulating layer 132 is greater than the thickness of the first gate insulating layer 131, the distance between the second gate G2 of the driving transistor Tdr and the second active region 142 is greater than the distance between the first gate G1 of the first switching transistor T1 and the first active region 141, which can make the subthreshold of the driving transistor Tdr greater than the subthreshold of the first switching transistor T1, thereby making the threshold voltage of the driving transistor Tdr greater than the threshold voltage of the first switching transistor T1. In this case, the driving capability of the driving transistor Tdr is greater than the driving capability of the first switching transistor T1, ensuring that the driving transistor Tdr can achieve grayscale expansion, improving the compatibility between the electrical characteristic range of the driving transistor Tdr and the pixel circuit 10. At the same time, the switching speed of the first switching transistor T1 is ensured, the compatibility between the electrical characteristic range of the first switching transistor T1 and the pixel circuit 10 is ensured, enabling the pixel circuit 10 to simultaneously consider both the switching speed of the first switching transistor T1 and the driving capability of the driving transistor Tdr, thereby improving the display effect of the display panel.

In some embodiments, a ratio range of the thickness of the second gate insulating layer 132 to the thickness of the first gate insulating layer 131 is 1.5 to 2.0, for example, the ratio of the thickness of the second gate insulating layer 132 to the thickness of the first gate insulating layer 131 can be 1.6, 1.7, 1.8, or 1.9.

In some embodiments, by setting the ratio of the thickness of the second gate insulating layer 132 to the thickness of the first gate insulating layer 131 to be greater than or equal to 1.5 and less than or equal to 2, a difference range between the subthreshold of the driving transistor Tdr and the subthreshold of the first switching transistor T1 can be made greater than or equal to 0.1 V/decade, thereby making a difference range between the threshold voltage of the driving transistor Tdr and the threshold voltage of the first switching transistor T1 be 0.3 V-2 V, enabling the pixel circuit 10 to simultaneously adapt to the electrical characteristic range of the driving transistor Tdr and the electrical characteristic range of the first switching transistor T1, improving the display effect of the display panel. Exemplarily, by setting the ratio of the thickness of the second gate insulating layer 132 to the thickness of the first gate insulating layer 131, the difference range between the subthreshold of the driving transistor Tdr and the subthreshold of the first switching transistor T1 can be made greater than or equal to 0.2 V/decade, and the difference range between the threshold voltage of the driving transistor Tdr and the threshold voltage of the first switching transistor T1 is in one embodiment 0.3 V-0.5 V, which can better enable the pixel circuit 10 to simultaneously adapt to the electrical characteristic range of the driving transistor Tdr and the electrical characteristic range of the first switching transistor T1, improving the display effect of the display panel.

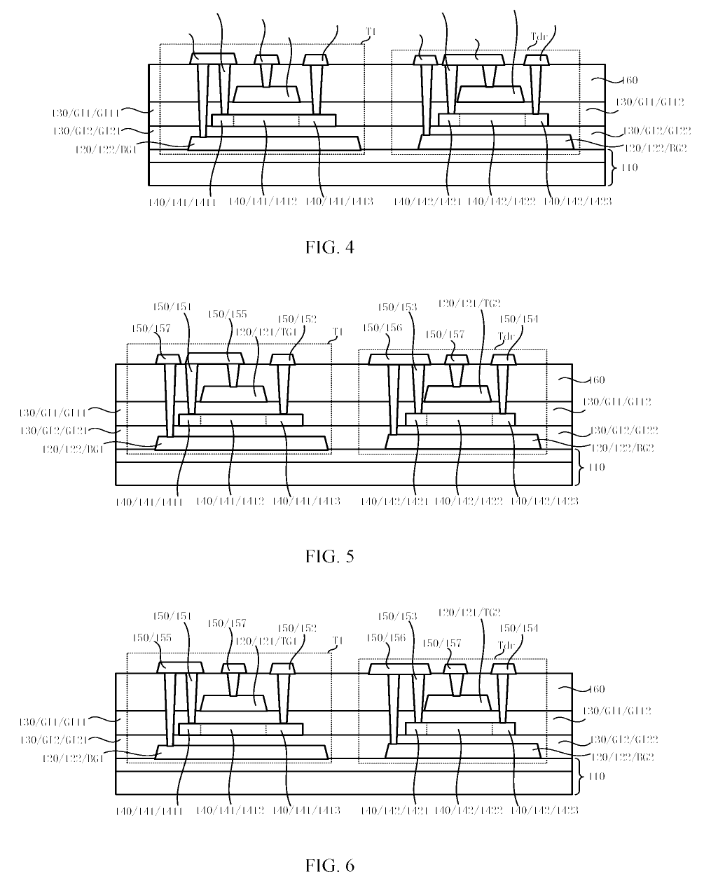

FIG. 4 is a schematic cross-sectional structural diagram of another array substrate provided by an embodiment of the present disclosure. As shown in FIG. 4, the gate layer 120 includes a top gate layer 121 and a bottom gate layer 122, and the gate insulating layer 130 includes a top gate insulating layer GI1 and a bottom gate insulating layer GI2; the bottom gate layer 122 is disposed on one side of the substrate 110, the bottom gate insulating layer GI2 is disposed on a side of the bottom gate layer 122 away from the substrate 110, the semiconductor layer 140 is disposed on a side of the bottom gate insulating layer GI2 away from the substrate 110, the top gate insulating layer GI1 is disposed on a side of the semiconductor layer 140 away from the substrate 110, and the top gate layer 121 is disposed on a side of the top gate insulating layer GI1 away from the substrate 110; the first gate G1 includes a first bottom gate BG1 and a first top gate TG1, and the second gate G2 includes a second bottom gate BG2 and a second top gate TG2; the bottom gate layer 122 includes the first bottom gate BG1 and the second bottom gate BG2, and the top gate layer 121 includes the first top gate TG1 and the second top gate TG2; the first gate insulating layer 131 includes a first top gate insulating layer GI11 and a first bottom gate insulating layer GI21, and the second gate insulating layer 132 includes a second top gate insulating layer GI12 and a second bottom gate insulating layer GI22; the first active region 141 includes a first source region 1411, a first channel region 1412, and a first drain region 1413, and the second active region 142 includes a second source region 1421, a second channel region 1422, and a second drain region 1423; the first bottom gate BG1 is connected to the first source region 1411, and the second top gate TG2 is connected to the second source region 1421; the thickness of the bottom gate insulating layer GI2 is greater than the thickness of the top gate insulating layer GI1.

In some embodiments, FIG. 4 exemplarily shows that the first switching transistor T1 and the driving transistor Tdr can be dual-gate transistors. In this case, the first switching transistor T1 and the driving transistor Tdr are four-terminal devices. The first top gate insulating layer GI11 and the second top gate insulating layer GI21 are located in the top gate insulating layer GI1, and the first bottom gate insulating layer GI21 and the second bottom gate insulating layer GI22 are located in the bottom gate insulating layer GI2. The first bottom gate BG1 is connected to the first source region 1411, that is, the first bottom gate BG1 of the first switching transistor T1 is connected to the source region, so the external terminals of the first switching transistor T1 are the source, the drain, and the first top gate TG1. In this case, the first top gate insulating layer GI11 between the first top gate TG1 and the first channel region 1412 serves as the gate insulating layer of the first switching transistor T1, so the thickness of the gate insulating layer of the first switching transistor T1 is the thickness of the top gate insulating layer GI1. Similarly, the second top gate TG2 is connected to the second source region 1421, that is, the second top gate TG2 of the driving transistor Tdr is connected to the source region, so the external terminals of the driving transistor Tdr are the source, the drain, and the second bottom gate BG2. In this case, the second bottom gate insulating layer GI22 between the second bottom gate BG2 and the second channel region 1422 serves as the gate insulating layer of the driving transistor Tdr, so the thickness of the gate insulating layer of the driving transistor Tdr is the thickness of the bottom gate insulating layer GI2. By setting the thickness of the bottom gate insulating layer GI2 to be greater than the thickness of the top gate insulating layer GI1, the thickness of the gate insulating layer of the driving transistor Tdr can be made greater than that of the first switching transistor T1, thereby making the subthreshold of the driving transistor Tdr greater than that of the first switching transistor T1, and further making the threshold voltage of the driving transistor Tdr greater than that of the first switching transistor T1. In this case, the driving capability of the driving transistor Tdr is greater than that of the first switching transistor T1, ensuring that the driving transistor Tdr can achieve grayscale expansion and improving the compatibility between the electrical range of the driving transistor Tdr and the pixel circuit 10. At the same time, the switching speed of the first switching transistor T1 is ensured, and the compatibility between the electrical range of the first switching transistor T1 and the pixel circuit 10 is ensured, allowing the pixel circuit 10 to simultaneously balance the switching speed of the first switching transistor T1 and the driving capability of the driving transistor Tdr, thereby improving the display effect of the display panel.

It should be noted that the structure of the bottom gate insulating layer GI2 may be a silicon oxide layer or a stacked structure of a silicon oxide layer and a silicon nitride layer. When forming the bottom gate insulating layer GI2, the threshold voltage of the transistor can be further precisely controlled by adjusting the film formation process conditions of the bottom gate insulating layer GI2. Exemplarily, the film formation process conditions of the bottom gate insulating layer GI2 may include the thickness of the bottom gate insulating layer GI2, the film formation temperature, and process parameters during the process. For example, when the process is chemical vapor deposition, the process parameters may include flow rate, power, and spacing. When the process is physical vapor deposition, the process parameters may include oxygen content. Similarly, when forming the top gate insulating layer GI1, the threshold voltage of the transistor can also be further precisely controlled by adjusting the film formation process conditions of the top gate insulating layer GI1. Exemplarily, the film formation process conditions of the top gate insulating layer GI1 may include the thickness of the bottom gate insulating layer GI2, the film formation temperature, and process parameters during the process. For example, when the process is chemical vapor deposition, the process parameters may include flow rate, power, and spacing. When the manufacturing process of the array substrate includes an annealing process, the conditions of the annealing process include an annealing temperature range of 150°C to 450°C, and the annealing atmosphere may be nitrogen or compressed dry air. When the array substrate includes an interlayer insulating layer 160, the structure of the interlayer insulating layer 160 may be a silicon oxide film layer or a stacked structure of a silicon oxide film layer and a silicon nitride film layer. When forming the interlayer insulating layer 160, the threshold voltage of the transistor can also be further precisely controlled by adjusting the film formation process conditions of the interlayer insulating layer 160. Exemplarily, the film formation process conditions of the interlayer insulating layer 160 may include the thickness of the interlayer insulating layer 160, the film formation temperature, and process parameters during the process. For example, when the process is chemical vapor deposition, the process parameters may include flow rate, power, and spacing.

FIG. 5 is a schematic cross-sectional structural diagram of another array substrate provided by an embodiment of the present disclosure. As shown in FIG. 5, the first top gate TG1 is connected to the first source region 1411, and the second bottom gate BG2 is connected to the second source region 1421; the thickness of the top gate insulating layer GI1 is greater than the thickness of the bottom gate insulating layer GI2.

In some embodiments, the difference between FIG. 5 and FIG. 4 is that the first top gate TG1 of the first switching transistor T1 is connected to the first source region 1411, that is, the first top gate TG1 of the first switching transistor T1 is connected to the source region, so the external terminals of the first switching transistor T1 are the source, the drain, and the first bottom gate BG1. At this time, the first bottom gate insulating layer GI21 between the first bottom gate BG1 of the first switching transistor T1 and the first channel region 1412 serves as the gate insulating layer of the first switching transistor T1, so the thickness of the gate insulating layer of the first switching transistor T1 is the thickness of the bottom gate insulating layer GI2. Similarly, the second bottom gate BG2 is connected to the second source region 1421, that is, the second bottom gate BG2 of the driving transistor Tdr is connected to the source region, so the external terminals of the driving transistor Tdr are the source, the drain, and the second top gate TG2. At this time, the second top gate insulating layer GI12 between the second top gate TG2 of the driving transistor Tdr and the second channel region 1422 serves as the gate insulating layer of the driving transistor Tdr, so the thickness of the gate insulating layer of the driving transistor Tdr is the thickness of the top gate insulating layer GI1. By setting the thickness of the top gate insulating layer GI1 to be greater than the thickness of the bottom gate insulating layer GI2, it is also possible to make the thickness of the gate insulating layer of the driving transistor Tdr greater than the thickness of the gate insulating layer of the first switching transistor T1, thereby enabling the sub-threshold of the driving transistor Tdr to be greater than the sub-threshold of the first switching transistor T1, and further making the threshold voltage of the driving transistor Tdr greater than the threshold voltage of the first switching transistor T1. At this time, the driving capability of the driving transistor Tdr is greater than the driving capability of the first switching transistor T1, ensuring that the driving transistor Tdr can achieve grayscale expansion and improving the compatibility of the electrical range of the driving transistor Tdr with the pixel circuit 10. At the same time, the switching speed of the first switching transistor T1 is ensured, and the compatibility of the electrical range of the first switching transistor T1 with the pixel circuit 10 is ensured, allowing the pixel circuit 10 to simultaneously consider both the switching speed of the first switching transistor T1 and the driving capability of the driving transistor Tdr, thereby improving the display effect of the display panel.

Continuing to refer to FIG. 4 and FIG. 5, the array substrate further includes:

a source-drain layer 150, the source-drain layer 150 is disposed on a side of the top gate layer 121 away from the semiconductor layer 140, and the source-drain layer 150 includes a first source 151, a first drain 152, a second source 153, and a second drain 154; the first source 151 is connected to the first source region 1411, the first drain 152 is connected to the first drain region 1413, the second source 153 is connected to the second source region 1421, and the second drain 154 is connected to the second drain region 1423.

In some embodiments, the material of the source-drain layer 150 is metal. The first source 151 is connected to the first source region 1411 and serves as the source of the first switching transistor T1, and the first drain 152 is connected to the first drain region 1413 and serves as the drain of the first switching transistor T1. The second source 153 is connected to the second source region 1421 and serves as the source of the first switching transistor T1, and the second drain 154 is connected to the second drain region 1423 and serves as the drain of the first switching transistor T1.

Continuing to refer to FIG. 4 and FIG. 5, the source-drain layer 150 further includes a first connection structure 155 and a second connection structure 156. The first bottom gate BG1 or the first top gate TG1 is connected to the first source region 1411 through the first connection structure 155, and the second top gate TG2 or the second bottom gate BG2 is connected to the second source region 1421 through the second connection structure 156.

In some embodiments, the first connection structure 155 is disposed in the same layer as the first source 151 and the first drain 152, and the first source 151 is connected to the first source region 1411. As shown in FIG. 4, when the first bottom gate BG1 is connected to the first source region 1411, the first bottom gate BG1 can be connected to the first source region 1411 through the first connection structure 155. As shown in FIG. 5, when the first top gate TG1 is connected to the first source region 1411, the first top gate TG1 can be connected to the first source region 1411 through the first connection structure 155. This ensures the connection reliability between the first bottom gate BG1 or the first top gate TG1 and the first source region 1411. Similarly, the second connection structure 156 is disposed in the same layer as the second source 153 and the second drain 154, and the second source 153 is connected to the second source region 1421. As shown in FIG. 4, when the second top gate TG2 is connected to the second source region 1421, the second top gate TG2 can be connected to the second source region 1421 through the second connection structure 156. As shown in FIG. 5, when the second bottom gate BG2 is connected to the second source region 1421, the second bottom gate BG2 can be connected to the second source region 1421 through the second connection structure 156. This ensures the connection reliability between the second top gate TG2 or the second bottom gate BG2 and the second source region 1421.

In addition, a gate lead 157 is further disposed on the source-drain layer 150. The gate lead 157 is connected to the external gate terminal of the transistor and is used to provide a driving signal to the gate of the transistor. For example, as shown in FIG. 4, the external gate terminal of the first switching transistor T1 is the first top gate TG1. At this time, a gate lead 157 is connected to the first top gate TG1 and is used to provide a driving signal to the first top gate TG1 of the first switching transistor T1. The external gate terminal of the driving transistor Tdr is the second bottom gate BG2. At this time, a gate lead 157 is connected to the second bottom gate BG2 and is used to provide a driving signal to the second bottom gate BG2 of the driving transistor Tdr.

Continuing to refer to FIG. 4 and FIG. 5, the array substrate further includes: an interlayer insulating layer 160 disposed between the top gate layer 121 and the source-drain layer 150, which can ensure insulation between the top gate layer 121 and the source-drain layer 150. Meanwhile, via holes are provided in the interlayer insulating layer 160, allowing the source and drain on the source-drain layer 150 to be connected to the source region and drain region on the semiconductor layer 140 through different via holes, respectively. In some embodiments, the channel length of the driving transistor Tdr may also be set to be greater than the channel length of the first switching transistor T1, and the subthreshold of the driving transistor Tdr is greater than the subthreshold of the first switching transistor T1, thereby making the threshold voltage of the driving transistor Tdr greater than the threshold voltage of the first switching transistor T1. In this case, the driving capability of the driving transistor Tdr is greater than the driving capability of the first switching transistor T1, ensuring that the driving transistor Tdr can achieve grayscale expansion and improving the compatibility of the electrical characteristics range of the driving transistor Tdr with the pixel circuit 10. At the same time, the switching speed of the first switching transistor T1 is ensured, and the compatibility of the electrical characteristics range of the first switching transistor T1 with the pixel circuit 10 is guaranteed, enabling the pixel circuit 10 to simultaneously balance the switching speed of the first switching transistor T1 and the driving capability of the driving transistor Tdr, thereby improving the display effect of the display panel. In some embodiments, the channel length of the driving transistor Tdr is 2 to 10 times that of the first switching transistor T1, which can also make the difference range between the subthreshold of the driving transistor Tdr and the subthreshold of the first switching transistor T1 greater than or equal to 0.1 V/decade, thereby allowing the difference range between the threshold voltage of the driving transistor Tdr and the threshold voltage of the first switching transistor T1 to be 0.3 V to 2 V. This enables the pixel circuit 10 to simultaneously adapt to the electrical characteristics range of the driving transistor Tdr and the electrical characteristics range of the first switching transistor T1, improving the display effect of the display panel. For example, by setting the ratio of the channel length of the driving transistor Tdr to the channel length of the first switching transistor T1, the difference range between the subthreshold of the driving transistor Tdr and the subthreshold of the first switching transistor T1 can be made greater than or equal to 0.2 V/decade, and the difference range between the threshold voltage of the driving transistor Tdr and the threshold voltage of the first switching transistor T1 is in one embodiment 0.3 V to 0.5 V. This allows the pixel circuit 10 to better simultaneously adapt to the electrical characteristics range of the driving transistor Tdr and the electrical characteristics range of the first switching transistor T1, thereby improving the display effect of the display panel. FIG. 6 is a schematic cross-sectional structural diagram of another array substrate provided by an embodiment of the present disclosure. As shown in FIG. 6, the array substrate further includes: a substrate 110; a gate layer 120 disposed on one side of the substrate 110, the gate layer 120 including a first gate G1 of the first switching transistor T1 and a second gate G2 of the driving transistor Tdr; a gate insulating layer 130 disposed on one side of the gate layer 120, the gate insulating layer 130 including a first gate insulating layer 131 and a second gate insulating layer 132, where an orthographic projection of the first gate G1 on the substrate 110 is located within an orthographic projection of the first gate insulating layer 131 on the substrate 110, and an orthographic projection of the second gate G2 on the substrate 110 is located within an orthographic projection of the second gate insulating layer 132 on the substrate 110; a semiconductor layer 140 disposed on a side of the gate insulating layer 130 away from the gate layer 120, the semiconductor layer 140 including a first active region 141 and a second active region 142, where an orthographic projection of the first active region 141 on the substrate 110 overlaps with an orthographic projection of the first gate G1 on the substrate 110, and an orthographic projection of the second active region 142 on the substrate 110 overlaps with an orthographic projection of the second gate G2 on the substrate 110; the first active region 141 includes a first source region 1411, a first channel region 1412, and a first drain region 1413, and the second active region 142 includes a second source region 1421, a second channel region 1422, and a second drain region 1423; the length of the second channel region 1422 is greater than the length of the first channel region 1412. In one embodiment, as shown in FIG. 6, the first source region 1411, the first channel region 1412, and the first drain region 1413 are arranged sequentially. The length of the first channel region 1412 is along the arrangement direction of the first source region 1411, the first channel region 1412, and the first drain region 1413. The second source region 1421, the second channel region 1422, and the second drain region 1423 are arranged sequentially, and the length of the second channel region 1422 is along the arrangement direction of the second source region 1421, the second channel region 1422, and the second drain region 1423. By setting the length of the second channel region 1422 to be greater than the length of the first channel region 1412, the threshold voltage of the driving transistor Tdr can be made greater than the threshold voltage of the first switching transistor T1. In this case, the driving capability of the driving transistor Tdr is greater than the driving capability of the first switching transistor T1, ensuring that the driving transistor Tdr can achieve grayscale expansion and improving the compatibility of the electrical characteristics range of the driving transistor Tdr with the pixel circuit 10. At the same time, the switching speed of the first switching transistor T1 is ensured, and the compatibility of the electrical characteristics range of the first switching transistor T1 with the pixel circuit 10 is guaranteed, enabling the pixel circuit 10 to simultaneously balance the switching speed of the first switching transistor T1 and the driving capability of the driving transistor Tdr, thereby improving the display effect of the display panel.

Continuing to refer to FIG. 6, the gate layer 120 includes a top gate layer 121 and a bottom gate layer 122, and the gate insulating layer 130 includes a top gate insulating layer GI1 and a bottom gate insulating layer GI2. The bottom gate layer 122 is disposed on one side of the substrate 110, the bottom gate insulating layer GI2 is disposed on a side of the bottom gate layer 122 away from the substrate 110, the semiconductor layer 140 is disposed on a side of the bottom gate insulating layer GI2 away from the substrate 110, the top gate insulating layer GI1 is disposed on a side of the semiconductor layer 140 away from the substrate 110, and the top gate layer 121 is disposed on a side of the top gate insulating layer GI1 away from the substrate 110. The first gate G1 includes a first bottom gate BG1 and a first top gate TG1, and the second gate G2 includes a second bottom gate BG2 and a second top gate TG2. The bottom gate layer 122 includes the first bottom gate BG1 and the second bottom gate BG2, and the top gate layer 121 includes the first top gate TG1 and the second top gate TG2. The first gate insulating layer 131 includes a first top gate insulating layer GI11 and a first bottom gate insulating layer GI21, and the second gate insulating layer 132 includes a second top gate insulating layer GI12 and a second bottom gate insulating layer GI22. The first bottom gate BG1 is connected to the first source region 1411, and the second bottom gate BG2 is connected to the second source region 1421.

In some embodiments, FIG. 6 exemplarily shows that the first bottom gate BG1 of the first switching transistor T1 is connected to the first source region 1411, so the external terminals of the first switching transistor T1 are the source, the drain, and the first top gate TG1. In this case, the gate insulating layer of the first switching transistor T1 is the first top gate insulating line GI11 between the first top gate TG1 and the first channel region 1412, which serves as the gate insulating layer of the first switching transistor T1. Thus, the thickness of the gate insulating layer of the first switching transistor T1 is the thickness of the top gate insulating layer GI1. The second bottom gate BG2 is connected to the second source region 1421, so the external terminals of the driving transistor Tdr are the source, the drain, and the second top gate TG2. Then, the gate insulating layer of the driving transistor Tdr is the second top gate insulating layer GI12 between the second top gate TG2 and the second channel region 1422, which serves as the gate insulating layer of the driving transistor Tdr. Thus, the thickness of the gate insulating layer of the driving transistor Tdr is the thickness of the top gate insulating layer GI1. In this case, the thickness of the gate insulating layer of the first switching transistor T1 is the same as that of the driving transistor Tdr. The first switching transistor T1 and the driving transistor Tdr change the threshold voltage difference between them through the difference in channel length.

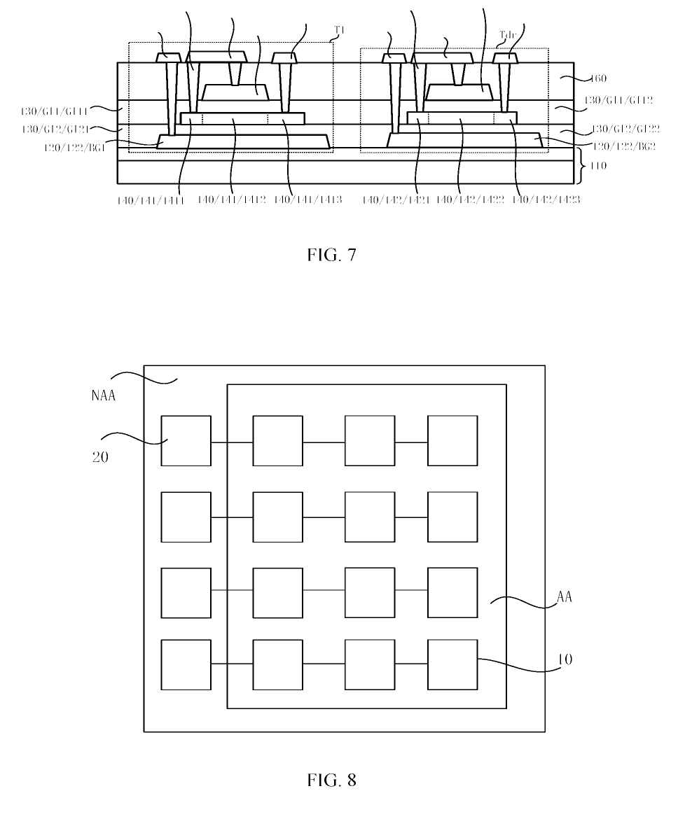

FIG. 7 is a schematic cross-sectional structural diagram of another array substrate provided by an embodiment of the present disclosure. As shown in FIG. 7, the first top gate TG1 is connected to the first source region 1411, and the second top gate TG2 is connected to the second source region 1421.

In one embodiment, the difference between FIG. 7 and FIG. 6 is that the first top gate TG1 is connected to the first source region 1411, and the second top gate TG2 is connected to the second source region 1421. In this case, the gate insulating layers of both the first switching transistor T1 and the driving transistor Tdr are the bottom gate insulating layer GI2. The thickness of the gate insulating layer of the first switching transistor T1 is the same as that of the driving transistor Tdr. The first switching transistor T1 and the driving transistor Tdr change the threshold voltage difference between them through the difference in channel length.

Continuing to refer to FIG. 6 and FIG. 7, the thickness of the bottom gate insulating layer GI2 is equal to the thickness of the top gate insulating layer GI1.

In some embodiments, when the channel length of the driving transistor Tdr is greater than that of the first switching transistor T1, causing the threshold voltage of the driving transistor Tdr to be greater than that of the first switching transistor T1, the thickness of the bottom gate insulating layer GI2 can be equal to that of the top gate insulating layer GI1, without affecting the difference between the threshold voltage of the driving transistor Tdr and that of the first switching transistor T1.

It should be noted that, in some embodiments, the thickness of the bottom gate insulating layer GI2 and the thickness of the top gate insulating layer GI1 may also be set to be unequal, which is not limited herein.

In some embodiments, when the channel length of the driving transistor Tdr is greater than that of the first switching transistor T1, the gate insulating layer of the first switching transistor T1 and the gate insulating layer of the driving transistor Tdr may also be set as different gate insulating layers, i.e., one is the top gate insulating layer GI1 and the other is the bottom gate insulating layer GI2. In this case, the thickness of the bottom gate insulating layer GI2 can also be set equal to that of the top gate insulating layer GI1, ensuring that the thickness of the gate insulating layer of the first switching transistor T1 is equal to that of the driving transistor Tdr, without affecting the difference between the threshold voltage of the driving transistor Tdr and that of the first switching transistor T1.

In some embodiments, the thickness of the gate insulating layer of the driving transistor Tdr may also be set greater than that of the first switching transistor T1, while the channel length of the driving transistor Tdr is greater than that of the first switching transistor T1. Thus, the difference between the threshold voltage of the driving transistor Tdr and that of the first switching transistor T1 can be adjusted simultaneously through the thickness of the gate insulating layer and the channel length, increasing the flexibility in adjusting the value of the threshold voltage difference between the driving transistor Tdr and the first switching transistor T1.

Based on the some embodiments, the first switching transistor is an N-type transistor, and the driving transistor is an N-type transistor, making the pixel circuit 10 entirely composed of N-type transistors. This can reduce the manufacturing cost of the display panel while ensuring good large-area uniformity of the display panel, which is beneficial for manufacturing medium-sized and large-sized display panels. At the same time, the threshold voltage of the driving transistor Tdr is greater than that of the first switching transistor T1, allowing both the electrical operating range of the driving transistor Tdr and that of the first switching transistor T1 to be adapted to the pixel circuit 10, thereby improving the yield and display performance of the display panel.

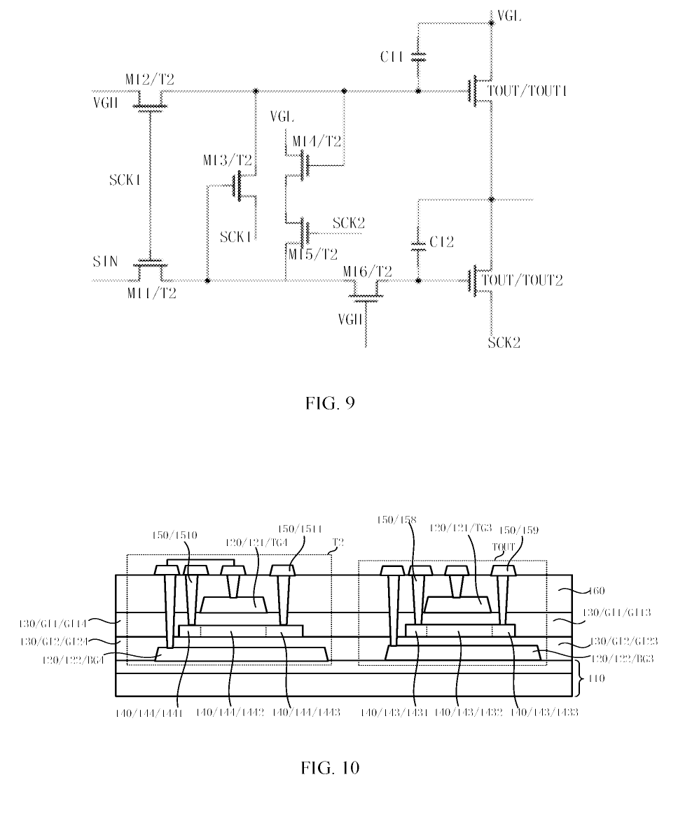

FIG. 8 is a schematic top view of another array substrate provided by an embodiment of the present disclosure. FIG. 9 is a schematic structural diagram of a gate driving circuit provided by an embodiment of the present disclosure. FIG. 10 is a schematic cross-sectional structural diagram of another array substrate provided by an embodiment of the present disclosure. As shown in FIG. 8 to FIG. 10, the array substrate further includes a gate driving circuit 20. The gate driving circuit 20 includes a second switching transistor T2 and an output transistor TOUT. The second switching transistor T2 is connected to the output transistor TOUT. The output transistor TOUT is connected to the first switching transistor T1. The second switching transistor T2 is configured to control a gate driving signal of the output transistor TOUT. The gate driving signal is configured to control a conduction state of the first switching transistor T1. The output transistor TOUT includes a third top gate TG3 and a third bottom gate BG3. The third top gate TG3 is connected to the second switching transistor T2. The third bottom gate BG3 is configured to input a first voltage. The first voltage is adjustable.

In some embodiments, the array substrate further includes a non-display area NAA. The gate driving circuit 20 is disposed in the non-display area NAA. The gate driving circuit 20 may include cascaded light emission control circuits and cascaded scan circuits. Referring to FIG. 2, each stage of the light emission control circuit is connected to a light emission control transistor M5 in a row of pixel circuits 10, and is configured to provide a light emission control signal to the row of light emission control transistors M5, and the light emission control transistor M5 is turned on during a light emission phase. A previous stage scan circuit is connected to a first initialization transistor M1 and a threshold compensation transistor M4 in a current row of pixel circuits 10, and is configured to control the first initialization transistor M1 and the threshold compensation transistor M4 to be turned on during a first phase to implement threshold voltage compensation. A current stage scan circuit is connected to a data write transistor M3 in the current row of pixel circuits 10, and is configured to control the data write transistor M3 to be turned on during a second phase to implement data writing. A next stage scan circuit is connected to a second initialization transistor M2 in the current row of pixel circuits 10, and is configured to control the second initialization transistor M2 to be turned on during a fourth phase to implement anode initialization of a light emitting device D1.

During operation of the gate driving circuit 20, the second switching transistor T2 serves as a switching transistor and is connected to the third top gate TG3 of the output transistor TOUT, and can control the gate driving signal of the third top gate TG3 of the output transistor TOUT to control the conduction state of the output transistor TOUT. For example, FIG. 9 exemplarily shows that the scan circuit in the gate driving circuit 20 includes six second switching transistors T2, two output transistors TOUT, and two capacitors. The six second switching transistors T2 are respectively a first transistor M11, a second transistor M12, a third transistor M13, a fourth transistor M14, a fifth transistor M15, and a sixth transistor M16. The two output transistors TOUT are respectively a first output transistor TOUT1 and a second output transistor TOUT2. The two capacitors are respectively a first storage capacitor C11 and a second storage capacitor C12. During operation of the gate driving circuit 20, a first clock signal SCK1, a second clock signal SCK2, a start signal SIN, a first power signal VGH, and a second power signal VGL are used to control the six second switching transistors T2 to be turned on or off, and the two output transistors TOUT can be respectively turned on to output the second clock signal SCK2 or the second power signal VGL. At this time, the third top gate TG3 of the first output transistor TOUT1 can be connected to a second electrode of the second transistor M12. A first electrode of the second transistor M12 is configured to receive the first power signal VGH. A gate of the second transistor M12 and a gate of the first transistor M11 receive the first clock signal SCK1. A first electrode of the first transistor M11 is configured to receive the start signal SIN. A second electrode of the first transistor M11 is connected to the third top gate TG3 of the second output transistor TOUT2 through the sixth transistor M16.

The third bottom gate BG3 of the output transistor TOUT is configured to input the first voltage. The first voltage is adjustable, and a potential of the third bottom gate BG3 of the output transistor TOUT can be independently adjusted. Therefore, the potential of the third bottom gate BG3 of the output transistor TOUT can be adjusted through the first voltage, and the potential of the third bottom gate BG3 is less than 0. Thus, a threshold voltage of the output transistor TOUT can be controlled to be greater than 0, avoiding a situation where a negative shift of the threshold voltage of the output transistor TOUT causes an abnormality in the gate driving signal output by the gate driving circuit 20. Meanwhile, on the basis of ensuring the performance of the output transistor TOUT, a process fluctuation range of the output transistor TOUT can be increased, which is beneficial to reducing the manufacturing difficulty and cost of the array substrate. For example, the third bottom gate BG3 of the first output transistor TOUT1 can input the first voltage, and/or the third bottom gate BG3 of the second output transistor TOUT2 can input the first voltage.

For example, FIG. 11 is a schematic diagram illustrating a correlation between a threshold voltage of an output transistor and performance of a gate driving circuit according to an embodiment of the present disclosure, where a horizontal coordinate represents a number of a display panel, a vertical coordinate represents the threshold voltage of the output transistor TOUT, solid circles are used to characterize that the performance of the gate driving circuit of the display panel is normal, and dashed circles are used to characterize that the performance of the gate driving circuit of the display panel is abnormal. As shown in FIG. 11, when the threshold voltage of the output transistor TOUT is greater than -1V, the discreteness of the output transistor TOUT can be ensured, thereby ensuring the output reliability of the gate driving circuit.

Continuing to refer to FIG. 10, a bottom gate layer 122 of the array substrate includes the third bottom gate BG3. A bottom gate insulating layer GI2 includes a third bottom gate insulating layer GI23. The third bottom gate insulating layer GI23 covers the third bottom gate BG3. A semiconductor layer 140 includes a third active region 143. The third active region 143 covers the third bottom gate insulating layer GI23. A top gate insulating layer GI1 includes a third top gate insulating layer GI13. The third top gate insulating layer GI13 covers the third active region 143. A top gate layer 121 includes the third top gate TG3. An orthographic projection of the third top gate TG3 on the substrate 110 overlaps with an orthographic projection of the third top gate insulating layer GI13 on the substrate 110.

In some embodiments, FIG. 10 exemplarily shows that the output transistor TOUT is a dual-gate transistor, i.e., the output transistor TOUT is a four-terminal device. In this case, the output transistor TOUT can be formed in the same process as the first switching transistor T1 and the driving transistor Tdr in the pixel circuit 10, meaning that the output transistor TOUT shares the same layer formation with the first switching transistor T1, utilizing identical film layer structures. By configuring the output transistor TOUT as a four-terminal device, independent adjustment of the third bottom gate BG3 can be achieved, thereby allowing the threshold voltage of the output transistor TOUT to be adjusted to be greater than 0. This avoids abnormal gate driving signals output by the gate driving circuit 20 due to negative bias in the threshold voltage of the output transistor TOUT.

Continuing with reference to FIG. 10, the second switching transistor T2 includes a fourth top gate TG4 and a fourth bottom gate BG4. The fourth top gate TG4 is located in the top gate layer 121, and the fourth bottom gate BG4 is located in the bottom gate layer 122. The potential of the fourth top gate TG4 is equal to the potential of the fourth bottom gate BG4.

In some embodiments, FIG. 10 exemplarily shows that the second switching transistor T2 is a dual-gate transistor, i.e., the second switching transistor T2 is a four-terminal device. This ensures that the transistors in the pixel circuit 10 and the transistors in the gate driving circuit 20 on the array substrate have the same structure, simplifying the manufacturing process of the array substrate. In this case, the second switching transistor T2 can also be formed in the same process as other transistors, allowing identical film layer structures of different transistors on the array substrate to share the same layer formation. When the second switching transistor T2 includes the fourth top gate TG4 and the fourth bottom gate BG4, and the potential of the fourth top gate TG4 is equal to the potential of the fourth bottom gate BG4, both the fourth top gate TG4 and the fourth bottom gate BG4 simultaneously form a current with the active region of the second switching transistor T2. This increases the current of the second switching transistor T2, making it greater than the current of the first switching transistor T1, thereby enhancing the driving capability of the second switching transistor T2. This improves the output capability of the gate driving circuit 20, which is beneficial for enhancing the display uniformity of the display panel and improving the display effect of the display panel.

Continuing with reference to FIG. 10, the connection between the fourth top gate TG4 and the fourth bottom gate BG4 ensures that their potentials are equal, increasing the current of the second switching transistor T2. For example, when the thickness of the top gate insulating layer GI1 is 150 nm and the thickness of the bottom gate insulating layer GI2 is 300 nm, the current of the second switching transistor T2 is more than 1.5 times greater than that of the first switching transistor T1, enhancing the driving capability of the second switching transistor T2 and thereby improving the output capability of the gate driving circuit 20.

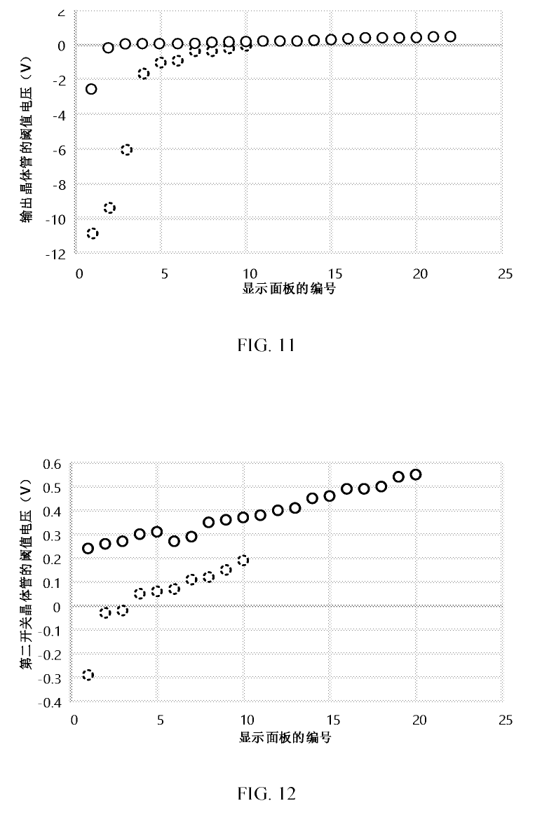

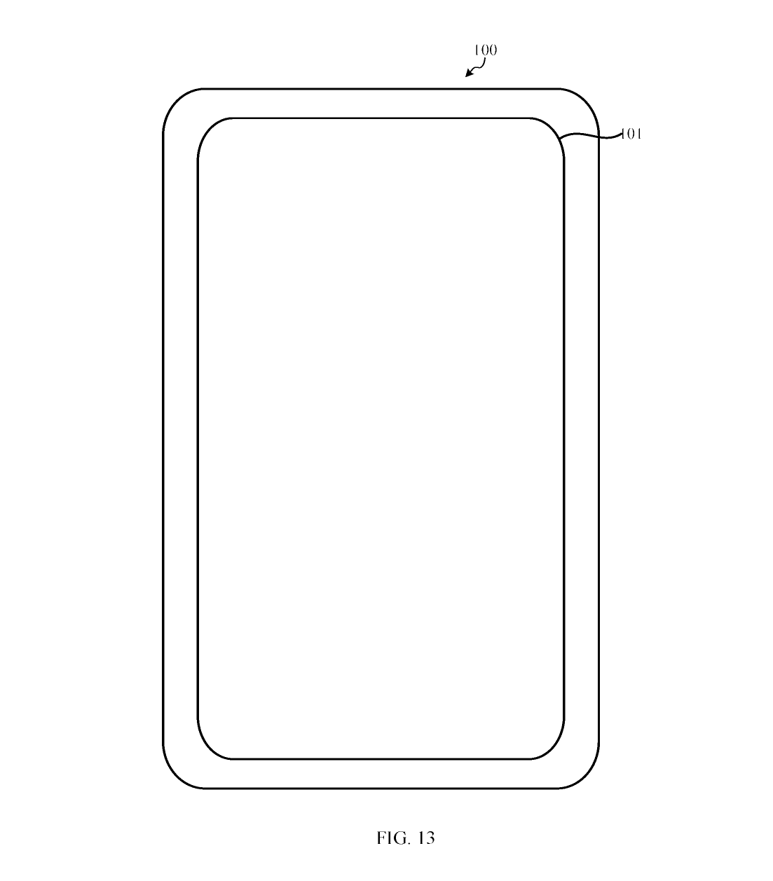

In some embodiments, FIG. 12 is a schematic diagram illustrating the correlation between the threshold voltage of a second switching transistor and the performance of a gate driving circuit according to an embodiment of the present disclosure. Here, the horizontal axis represents the serial numbers of display panels, the vertical axis represents the threshold voltage of the second switching transistor T2, solid circles indicate normal performance of the gate driving circuit in the display panel, and dashed circles indicate abnormal performance of the gate driving circuit in the display panel. As shown in FIG. 12, when the threshold voltage of the second switching transistor T2 is greater than 0.25 V, it can be ensured that the turn-off voltage Voff of the second switching transistor T2 is greater than 0, thereby guaranteeing normal performance of the gate driving circuit.

Continuing with reference to FIG. 10, the bottom gate insulating layer GI2 includes a fourth bottom gate insulating layer GI24, which covers the fourth bottom gate BG4. The semiconductor layer 140 includes a fourth active region 144, which covers the fourth bottom gate insulating layer GI24. The top gate insulating layer GI1 includes a fourth top gate insulating layer GI14, which covers the fourth active region 144. The orthographic projection of the fourth top gate TG4 on the substrate 110 overlaps with the orthographic projection of the fourth top gate insulating layer GI14 on the substrate 110. The third active region 143 includes a third source region 1431, a third channel region 1432, and a third drain region 1433. The fourth active region 144 includes a fourth source region 1441, a fourth channel region 1442, and a fourth drain region 1443. The source-drain layer 150 includes a third source 158, a third drain 159, a fourth source 1510, and a fourth drain 1511. The third source 158 is connected to the third source region 1431, the third drain 159 is connected to the third drain region 1433, the fourth source 1510 is connected to the fourth source region 1441, and the fourth drain 1511 is connected to the fourth drain region 1443.

In some embodiments, the fourth bottom gate BG4 of the second switching transistor T2 is located in the bottom gate layer 122, the fourth top gate TG4 is located in the top gate layer 121, the fourth bottom gate insulating layer GI24 is located in the bottom gate insulating layer GI2, the fourth top gate insulating layer GI14 is located in the top gate insulating layer GI1, the fourth active region 144 is located in the semiconductor layer 140, and the fourth source 1510 and the fourth drain 1511 are located in the source-drain layer 150. This arrangement ensures that each film layer of the second switching transistor T2 is located within the same film layer as the corresponding film layer structures of other transistors, simplifying the structure and manufacturing process flow of the array substrate. The third source region 1431, the third channel region 1432, and the third drain region 1433 are sequentially arranged, and the fourth source region 1441, the fourth channel region 1442, and the fourth drain region 1443 are sequentially arranged. The third source 158 is connected to the third source region 1431, serving as the source of the output transistor TOUT, and the third drain 159 is connected to the third drain region 1433, serving as the drain of the output transistor TOUT. The fourth source 1510 is connected to the fourth source region 1441, serving as the source of the second switching transistor T2, and the fourth drain 1511 is connected to the fourth drain region 1443, serving as the drain of the second switching transistor T2.

In some embodiments, the source-drain layer further includes a third connection structure, and the fourth top gate is connected to the fourth bottom gate via the third connection structure.

In some embodiments, the third connection structure is located in the source-drain layer and can extend to the fourth top gate and the fourth bottom gate through vias, ensuring that the fourth top gate can be connected to the fourth bottom gate via the third connection structure. This guarantees the reliability of the connection between the fourth top gate and the fourth bottom gate.

Embodiments of the present disclosure also provide an array substrate. The array substrate includes a gate driving circuit; the gate driving circuit includes a second switching transistor and an output transistor, the second switching transistor is connected to the output transistor, and the output transistor is configured to output a gate driving signal; the output transistor includes a third top gate and a third bottom gate; the third top gate is connected to the second switching transistor, and the third bottom gate is configured to receive a first voltage; and the first voltage is adjustable.

In some embodiments, the third top gate is connected to the second switching transistor, enabling the second switching transistor to control the potential of the third top gate, thereby controlling the conduction state of the output transistor, and the output transistor can output the gate driving signal. The third bottom gate is configured to receive the first voltage, which is adjustable, allowing the potential of the third bottom gate of the output transistor to be independently adjusted. Thus, the potential of the third bottom gate of the output transistor can be regulated via the first voltage, making the potential of the third bottom gate less than 0. Consequently, the threshold voltage of the output transistor can be controlled to be greater than 0, avoiding abnormal gate driving signals output by the gate driving circuit due to negative bias of the output transistor's threshold voltage. Simultaneously, while ensuring the performance of the output transistor, the process fluctuation range of the output transistor can be increased, which is beneficial for reducing the manufacturing difficulty and cost of the array substrate.

In some embodiments, the array substrate further includes:

a substrate;

a bottom gate layer disposed on one side of the substrate, the bottom gate layer including the third bottom gate;

a bottom gate insulating layer disposed on a side of the bottom gate layer away from the substrate, the bottom gate insulating layer including a third bottom gate insulating layer covering the third bottom gate;

a semiconductor layer disposed on a side of the bottom gate insulating layer away from the substrate, the semiconductor layer including a third active region covering the third bottom gate insulating layer;

a top gate insulating layer disposed on a side of the semiconductor layer away from the substrate; the top gate insulating layer including a third top gate insulating layer covering the third active region;

a top gate layer disposed on a side of the top gate insulating layer away from the substrate, the top gate layer including the third top gate, and an orthographic projection of the third top gate on the substrate overlaps with an orthographic projection of the third top gate insulating layer on the substrate.

In some embodiments, the second switching transistor includes a fourth top gate and a fourth bottom gate, the fourth top gate is located in the top gate layer, the fourth bottom gate is located in the bottom gate layer, and the potential of the fourth top gate is equal to the potential of the fourth bottom gate.

In some embodiments, the fourth top gate and the fourth bottom gate are connected.

In some embodiments, the bottom gate insulating layer includes a fourth bottom gate insulating layer covering the fourth bottom gate; the semiconductor layer includes a fourth active region covering the fourth bottom gate insulating layer; the top gate insulating layer includes a fourth top gate insulating layer covering the fourth active region; an orthographic projection of the fourth top gate on the substrate overlaps with an orthographic projection of the fourth top gate insulating layer on the substrate; the third active region includes a third source region, a third channel region, and a third drain region; the fourth active region includes a fourth source region, a fourth channel region, and a fourth drain region;

the array substrate further includes:

a source-drain layer, the source-drain layer disposed on a side of the top gate layer away from the semiconductor layer, the source-drain layer including a third source electrode, a third drain electrode, a fourth source electrode, and a fourth drain electrode; the third source electrode is connected to the third source region, the third drain electrode is connected to the third drain region, the fourth source electrode is connected to the fourth source region, and the fourth drain electrode is connected to the fourth drain region;

In some embodiments, the source-drain layer further includes a third connection structure, and the fourth top gate is connected to the fourth bottom gate through the third connection structure.

Embodiments of the present disclosure also provide a display panel. FIG. 13 is a schematic structural diagram of a display panel according to an embodiment of the present disclosure. As shown in FIG. 13, the display panel 100 includes the array substrate 101 provided in any embodiment of the present disclosure. Since the display panel 100 includes the array substrate 101 provided in any embodiment of the present disclosure, it has the same beneficial effects as the array substrate 101 provided in any embodiment of the present disclosure, which will not be repeated here. The display panel 100 may be, for example, any product or component with a display function, such as a mobile phone, tablet computer, television, monitor, laptop, digital photo frame, smart wearable device, information inquiry machine in a public hall, etc.

Note that the above are only preferred embodiments of the present disclosure and the applied technical principles. Those will understand that the present disclosure is not limited to the specific embodiments described herein, and various changes, readjustments, and substitutions can be made in the art without departing from the claimed scope of the present disclosure. Therefore, although the present disclosure has been described in detail through the above embodiments, the present disclosure is not limited to the above embodiments, and may include more other equivalent embodiments without departing from the concept of the present disclosure, and the scope of the present disclosure is defined by the appended claims.

1. An array substrate, comprising a pixel circuit, the pixel circuit comprising a first switching transistor and a driving transistor; the first switching transistor is connected to the driving transistor, the first switching transistor is configured to control a gate potential and a first electrode potential of the driving transistor, and the driving transistor is configured to form a driving current according to the gate potential and the first electrode potential; a threshold voltage of the driving transistor is greater than a threshold voltage of the first switching transistor.

2. The array substrate according to claim 1, further comprising:
a substrate;
a gate layer disposed on one side of the substrate, the gate layer comprising a first gate of the first switching transistor and a second gate of the driving transistor;
a gate insulating layer disposed on one side of the gate layer, the gate insulating layer comprising a first gate insulating layer and a second gate insulating layer, an orthographic projection of the first gate on the substrate being located within an orthographic projection of the first gate insulating layer on the substrate, an orthographic projection of the second gate on the substrate being located within an orthographic projection of the second gate insulating layer on the substrate; a thickness of the second gate insulating layer is greater than a thickness of the first gate insulating layer;
a semiconductor layer disposed on a side of the gate insulating layer away from the gate layer, the semiconductor layer comprising a first active region and a second active region, an orthographic projection of the first active region on the substrate overlapping with the orthographic projection of the first gate on the substrate, an orthographic projection of the second active region on the substrate overlapping with the orthographic projection of the second gate on the substrate;
a ratio of the thickness of the second gate insulating layer to the thickness of the first gate insulating layer ranges from 1.5 to 2.

3. The array substrate according to claim 2, wherein the gate layer comprises a top gate layer and a bottom gate layer, and the gate insulating layer comprises a top gate insulating layer and a bottom gate insulating layer; the bottom gate layer is disposed on one side of the substrate, the bottom gate insulating layer is disposed on a side of the bottom gate layer away from the substrate, the semiconductor layer is disposed on a side of the bottom gate insulating layer away from the substrate, the top gate insulating layer is disposed on a side of the semiconductor layer away from the substrate, and the top gate layer is disposed on a side of the top gate insulating layer away from the substrate;
the first gate comprises a first bottom gate and a first top gate, and the second gate comprises a second bottom gate and a second top gate; the bottom gate layer comprises the first bottom gate and the second bottom gate, and the top gate layer comprises the first top gate and the second top gate; the first gate insulating layer comprises a first top gate insulating layer and a first bottom gate insulating layer, and the second gate insulating layer comprises a second top gate insulating layer and a second bottom gate insulating layer; the first active region comprises a first source region, a first channel region, and a first drain region, and the second active region comprises a second source region, a second channel region, and a second drain region;
the first bottom gate is connected to the first source region, and the second top gate is connected to the second source region; a thickness of the bottom gate insulating layer is greater than a thickness of the top gate insulating layer; or, the first top gate is connected to the first source region, and the second bottom gate is connected to the second source region; a thickness of the top gate insulating layer is greater than a thickness of the bottom gate insulating layer.

4. The array substrate according to claim 3, further comprising:
a source-drain layer, the source-drain layer disposed on a side of the top gate layer away from the semiconductor layer, the source-drain layer comprising a first source electrode, a first drain electrode, a second source electrode, and a second drain electrode; the first source electrode is connected to the first source region, the first drain electrode is connected to the first drain region, the second source electrode is connected to the second source region, and the second drain electrode is connected to the second drain region;
the source-drain layer further comprises a first connection structure and a second connection structure, the first bottom gate or the first top gate is connected to the first source region through the first connection structure, and the second top gate or the second bottom gate is connected to the second source region through the second connection structure.

5. The array substrate according to claim 4, further comprising:
an interlayer insulating layer disposed between the top gate layer and the source-drain layer.

6. The array substrate according to claim 1, wherein a channel length of the driving transistor is greater than a channel length of the first switching transistor;
the channel length of the driving transistor is 2 to 10 times the channel length of the first switching transistor.

7. The array substrate according to claim 6, further comprising:
a substrate;
a gate layer disposed on one side of the substrate, the gate layer comprising a first gate of the first switching transistor and a second gate of the driving transistor;
a gate insulating layer disposed on one side of the gate layer, the gate insulating layer comprising a first gate insulating layer and a second gate insulating layer, an orthographic projection of the first gate on the substrate being located within an orthographic projection of the first gate insulating layer on the substrate, an orthographic projection of the second gate on the substrate being located within an orthographic projection of the second gate insulating layer on the substrate;
a semiconductor layer disposed on a side of the gate insulating layer away from the gate layer, the semiconductor layer comprising a first active region and a second active region, an orthographic projection of the first active region on the substrate overlapping with the orthographic projection of the first gate on the substrate, an orthographic projection of the second active region on the substrate overlapping with the orthographic projection of the second gate on the substrate; the first active region comprises a first source region, a first channel region, and a first drain region, and the second active region comprises a second source region, a second channel region, and a second drain region; a length of the second channel region is greater than a length of the first channel region.

8. The array substrate according to claim 7, wherein the gate layer comprises a top gate layer and a bottom gate layer, and the gate insulating layer comprises a top gate insulating layer and a bottom gate insulating layer; the bottom gate layer is disposed on a side of the substrate, the bottom gate insulating layer is disposed on a side of the bottom gate layer away from the substrate, the semiconductor layer is disposed on a side of the bottom gate insulating layer away from the substrate, the top gate insulating layer is disposed on a side of the semiconductor layer away from the substrate, and the top gate layer is disposed on a side of the top gate insulating layer away from the substrate;
the first gate comprises a first bottom gate and a first top gate, and the second gate comprises a second bottom gate and a second top gate; the bottom gate layer comprises the first bottom gate and the second bottom gate, and the top gate layer comprises the first top gate and the second top gate; the first gate insulating layer comprises a first top gate insulating layer and a first bottom gate insulating layer, and the second gate insulating layer comprises a second top gate insulating layer and a second bottom gate insulating layer;
the first bottom gate is connected to the first source region, and the second bottom gate is connected to the second source region; or, the first top gate is connected to the first source region, and the second top gate is connected to the second source region;
a thickness of the bottom gate insulating layer is equal to a thickness of the top gate insulating layer.

9. The array substrate according to claim 1, wherein the first switching transistor is an N-type transistor, and the driving transistor is an N-type transistor.

10. The array substrate according to claim 1, further comprising a gate driving circuit, the gate driving circuit comprising a second switching transistor and an output transistor, the second switching transistor being connected to the output transistor, the output transistor being connected to the first switching transistor, the second switching transistor being configured to control a gate driving signal of the output transistor, and the gate driving signal being configured to control a conduction state of the first switching transistor; the output transistor comprises a third top gate and a third bottom gate; the third top gate is connected to the second switching transistor, and the third bottom gate is configured to receive a first voltage; wherein the first voltage is adjustable.

11. The array substrate according to claim 10, wherein a bottom gate layer of the array substrate comprises the third bottom gate;
a bottom gate insulating layer of the array substrate comprises a third bottom gate insulating layer, the third bottom gate insulating layer covering the third bottom gate;
a semiconductor layer of the array substrate comprises a third active region, the third active region covering the third bottom gate insulating layer;
a top gate insulating layer of the array substrate comprises a third top gate insulating layer, the third top gate insulating layer covering the third active region;
a top gate layer of the array substrate comprises the third top gate, and an orthographic projection of the third top gate on the substrate overlaps with an orthographic projection of the third top gate insulating layer on the substrate.

12. The array substrate according to claim 10, wherein the second switching transistor comprises a fourth top gate and a fourth bottom gate, the fourth top gate is located in the top gate layer, the fourth bottom gate is located in the bottom gate layer, and a potential of the fourth top gate is equal to a potential of the fourth bottom gate;
the fourth top gate and the fourth bottom gate are connected.

13. The array substrate according to claim 11, wherein the bottom gate insulating layer comprises a fourth bottom gate insulating layer, the fourth bottom gate insulating layer covering the fourth bottom gate; the semiconductor layer comprises a fourth active region, the fourth active region covering the fourth bottom gate insulating layer; the top gate insulating layer comprises a fourth top gate insulating layer, the fourth top gate insulating layer covering the fourth active region; an orthographic projection of the fourth top gate on the substrate overlaps with an orthographic projection of the fourth top gate insulating layer on the substrate; the third active region comprises a third source region, a third channel region, and a third drain region; the fourth active region comprises a fourth source region, a fourth channel region, and a fourth drain region;
a source-drain layer of the array substrate comprises a third source, a third drain, a fourth source, and a fourth drain; the third source is connected to the third source region, the third drain is connected to the third drain region, the fourth source is connected to the fourth source region, and the fourth drain is connected to the fourth drain region.

14. The array substrate according to claim 13, wherein the source-drain layer further comprises a third connection structure, and the fourth top gate is connected to the fourth bottom gate through the third connection structure.

15. An array substrate, comprising a gate driving circuit; the gate driving circuit comprises a second switching transistor and an output transistor, the second switching transistor is connected to the output transistor, and the output transistor is configured to output a gate driving signal; the output transistor comprises a third top gate and a third bottom gate; the third top gate is connected to the second switching transistor, and the third bottom gate is configured to receive a first voltage; wherein the first voltage is adjustable.

16. The array substrate according to claim 15, further comprising:
a substrate;
a bottom gate layer disposed on a side of the substrate, the bottom gate layer comprising the third bottom gate;
a bottom gate insulating layer disposed on a side of the bottom gate layer away from the substrate, the bottom gate insulating layer comprising a third bottom gate insulating layer, the third bottom gate insulating layer covering the third bottom gate;
a semiconductor layer disposed on a side of the bottom gate insulating layer away from the substrate, the semiconductor layer comprising a third active region, the third active region covering the third bottom gate insulating layer;
a top gate insulating layer disposed on a side of the semiconductor layer away from the substrate; the top gate insulating layer comprising a third top gate insulating layer, the third top gate insulating layer covering the third active region;
a top gate layer disposed on a side of the top gate insulating layer away from the substrate, the top gate layer comprising a third top gate, and an orthographic projection of the third top gate on the substrate overlapping with an orthographic projection of the third top gate insulating layer on the substrate.

17. The array substrate according to claim 16, wherein the second switching transistor comprises a fourth top gate and a fourth bottom gate, the fourth top gate is located in the top gate layer, the fourth bottom gate is located in the bottom gate layer, and a potential of the fourth top gate is equal to a potential of the fourth bottom gate; the fourth top gate and the fourth bottom gate are connected.

18. The array substrate according to claim 16, wherein the bottom gate insulating layer comprises a fourth bottom gate insulating layer, the fourth bottom gate insulating layer covering the fourth bottom gate; the semiconductor layer comprises a fourth active region, the fourth active region covering the fourth bottom gate insulating layer; the top gate insulating layer comprises a fourth top gate insulating layer, the fourth top gate insulating layer covering the fourth active region; an orthographic projection of the fourth top gate on the substrate overlaps with an orthographic projection of the fourth top gate insulating layer on the substrate; the third active region comprises a third source region, a third channel region, and a third drain region; the fourth active region comprises a fourth source region, a fourth channel region, and a fourth drain region.

19. The array substrate according to claim 18, wherein the array substrate further comprises:
a source-drain layer, the source-drain layer disposed on a side of the top gate layer away from the semiconductor layer, the source-drain layer comprising a third source, a third drain, a fourth source, and a fourth drain; the third source is connected to the third source region, the third drain is connected to the third drain region, the fourth source is connected to the fourth source region, and the fourth drain is connected to the fourth drain region;
the source-drain layer further comprises a third connection structure, and the fourth top gate is connected to the fourth bottom gate through the third connection structure.

20. A display panel, comprising the array substrate according to claim 1.
